(19) United States
(12) Patent Application Publication
(10) Pub. No.: US 2023/0242790 A1
(43) Pub. Date: Aug. 3, 2023

(54) CERIA-BASED SLURRY COMPOSITIONS FOR SELECTIVE AND NONSELECTIVE CMP OF SILICON OXIDE, SILICON NITRIDE, AND POLYSILICON

(71) Applicant: CMC Materials, Inc., Aurora, IL (US)

(72) Inventors: Brian Reiss, Woodridge, IL (US); Juyeon Chang, Bolingbrook, IL (US); Shengyu Jin, Bolingbrook, IL (US); Helin Huang, Aurora, IL (US)

(21) Appl. No.: 17/592,279

(22) Filed: Feb. 3, 2022

(51) Int. Cl. C09G 1/02; H01L 21/3105; H01L 21/321

(52) U.S. Cl. CPC C09G 1/02; H01L 21/31053; H01L 21/3212

(57) ABSTRACT

The invention provides a chemical-mechanical polishing composition comprising: (a) ceria abrasive particles; (b) a cationic polymer; (c) a buffer; and (d) water, wherein the polishing composition has a pH of about 6 to about 9. The invention also provides a method of chemically-mechanically polishing a substrate, especially a substrate comprising silicon oxide, silicon nitride, and polysilicon, using the inventive polishing composition.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

As the size of integrated circuits is reduced and the number of integrated circuits on a chip increases, the components that make up the circuits must be positioned closer together in order to comply with the limited space available on a typical chip. Effective isolation between circuits is important for ensuring optimum semiconductor performance. To that end, shallow trenches are etched into the semiconductor substrate and filled with insulating material to isolate active regions of the integrated circuit. More specifically, shallow trench isolation (STI) is a process in which a silicon nitride layer is formed on a silicon substrate, shallow trenches are formed via etching or photolithography, and a dielectric layer is deposited to fill the trenches. Due to variation in the depth of trenches formed in this manner, it is typically necessary to deposit an excess of dielectric material on top of the substrate to ensure complete filling of all trenches. The dielectric material (e.g., a silicon oxide) conforms to the underlying topography of the substrate. Thus, the surface of the substrate is characterized by raised areas of the overlying oxide between trenches, which are referred to as pattern oxide. Pattern oxide is characterized by the step height of the excess oxide dielectric material lying outside of the trenches. The excess dielectric material is typically removed by a CMP process, which additionally provides a planar surface for further processing. As pattern oxide is abraded and planarity of the surface is approached, the oxide layer is then referred to as blanket oxide.

A polishing composition can be characterized according to its polishing rate (i.e., removal rate) and its planarization efficiency. The polishing rate refers to the rate of removal of a material from the surface of the substrate and is usually expressed in terms of units of length (thickness) per unit of time (e.g., Angstroms (Å) per minute). Planarization efficiency relates to step height reduction versus amount of material removed from the substrate. Specifically, a polishing surface, e.g., a polishing pad, first contacts the “high points” of the surface and must remove material in order to form a planar surface. A process that results in achieving a planar surface with less removal of material is considered to be more efficient than a process requiring removal of more material to achieve planarity.

Often the desirable rates of removal of silicon oxide, silicon nitride, and polysilicon can vary depending on the application. For example, in some instances silicon oxide pattern can be rate-limiting for the dielectric polishing step in STI processes, and therefore high removal rates of the silicon oxide pattern are desired to increase device throughput. However, if the blanket removal rate is too rapid, overpolishing of oxide in exposed trenches results in trench erosion and increased device defectivity. Thus, in some instances (e.g., for polishing applications) it is desirable to have rates of removal of silicon oxide, silicon nitride, and polysilicon that are similar, e.g., a 1:1:1 selectivity.

A need remains for compositions and methods for chemical-mechanical polishing that can remove silicon oxide, silicon nitride and polysilicon with near to 1:1:1 selectivity, but can be adjusted to selectively remove silicon oxide, silicon nitride, and/or polysilicon as compared to other dielectric materials.

The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) ceria abrasive particles; (b) a cationic polymer; (c) a buffer; and (d) water, wherein the polishing composition has a pH of about 6 to about 9.

The invention further provides a method of chemically-mechanically polishing a substrate comprising: (i) providing a substrate, (ii) providing a polishing pad, (iii) providing a chemical-mechanical polishing composition comprising: (a) ceria abrasive particles; (b) a cationic polymer; (c) a buffer; and (d) water, wherein the polishing composition has a pH of about 6 to about 9, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### DETAILED DESCRIPTION OF THE INVENTION

The invention provides a chemical-mechanical polishing composition comprising, consisting essentially of, or consisting of: (a) ceria abrasive particles; (b) a cationic polymer; (c) a buffer; and (d) water, wherein the polishing composition has a pH of about 6 to about 9.

The chemical-mechanical polishing composition comprises ceria abrasive particles. As used herein, the phrase “ceria abrasive particles” can be used interchangeably with “abrasive,” “ceria particles,” or “ceria abrasive.” As is well known, ceria is an oxide of the rare earth metal cerium, and is also known as ceric oxide, cerium oxide (e.g., cerium(IV) oxide), or cerium dioxide. Cerium(IV) oxide (CeO₂) can be formed by calcining cerium oxalate or cerium hydroxide. Cerium also forms cerium(III) oxides such as, for example, Ce₂O₃. The ceria abrasive particles can comprise any one or more of these or other oxides of ceria.

The ceria abrasive particles can be of any suitable type. In an embodiment, the ceria abrasive particles comprise, consist essentially of, or consist of calcined ceria particles, wet ceria particles, wet-based process ceria particles or combinations thereof. In a preferred embodiment, the ceria abrasive particles comprise wet ceria particles or wet process-based ceria particles.

As used herein, “wet ceria particles” or “wet process-based ceria particles” (collectively herein “wet process” ceria particles) refers to a ceria prepared by a precipitation, condensation-polymerization, or similar process (as opposed to, for example, fumed or pyrogenic ceria). A polishing composition of the invention comprising wet-process ceria particles has been found to exhibit lower defects when used to polish substrates according to a method of the invention. Without wishing to be bound to a particular theory, it is believed that wet-process ceria comprises approximately spherical ceria particles and/or smaller aggregate ceria particles, thereby resulting in lower substrate defectivity when used in the inventive method. Illustrative examples of wet-process ceria are HC30™ and HC60™ ceria commercially available from Rhodia and Hybrid-30 commercially available from ANP Co., Ltd.

The ceria abrasive particles can have any suitable average size (i.e., average particle diameter). If the average ceria abrasive particle size is too small, the polishing composition may not exhibit sufficient removal rate. In contrast, if the average ceria abrasive particle size is too large, the polishing composition may exhibit undesirable polishing performance such as, for example, poor substrate defectivity. Accordingly, the ceria abrasive particles can have an average particle size of about 10 nm or more, for example, about 15 nm or more, about 20 nm or more, about 25 nm or more, about 30 nm or more, about 35 nm or more, about 40 nm or more, about 45 nm or more, or about 50 nm or more. Alternatively, or in addition, the ceria abrasive particles can have an average particle size of about 1000 nm or less, for example, about 750 nm or less, about 500 nm or less, about 250 nm or less, about 150 nm or less, about 100 nm or less, about 75 nm or less, or about 50 nm or less. Thus, the ceria abrasive particles can have an average particle size bounded by any two of the aforementioned endpoints. For example, the ceria abrasive particles can have an average particle size of about 10 nm to about 1000 nm, e.g., about 10 nm to about 750 nm, about 15 nm to about 500 nm, about 20 nm to about 250 nm, about 20 nm to about 150 nm, about 25 nm to about 150 nm, about 25 nm to about 100 nm, about 50 nm to about 150 nm, or about 50 nm to about 100 nm. For spherical ceria abrasive particles, the size of the particle is the diameter of the particle. For non-spherical ceria particles, the size of the particle is the diameter of the smallest sphere that encompasses the particle. The particle size of the ceria abrasive particles can be measured using any suitable technique, for example, using laser diffraction techniques. Suitable particle size measurement instruments are available from, for example, Malvern Instruments (Malvern, UK).

In some embodiments, the ceria abrasive particles of the polishing composition exhibit a multimodal particle size distribution. As used herein, the term “multimodal” means that the ceria abrasive particles exhibit an average particle size distribution having at least 2 maxima (e.g., 2 or more maxima, 3 or more maxima, 4 or more maxima, or 5 or more maxima). Preferably, in these embodiments, the ceria abrasive particles exhibit a bimodal particle size distribution, i.e., the ceria abrasive particles exhibit a particle size distribution having 2 average particle size maxima. The terms “maximum” and “maxima” mean a peak or peaks in the particle size distribution. The peak or peaks correspond to the average particle sizes described herein for the ceria abrasive particles. Thus, for example, a plot of the number of particles versus particle size will reflect a bimodal particle size distribution, with a first peak in the particle size range of about 75 nm to about 150 nm, for example, about 80 nm to about 140 nm, about 85 nm to about 130 nm, or about 90 nm to about 120 nm, and a second peak in the particle size range of about 25 nm to about 70 nm, for example, about 30 nm to about 65 nm, about 35 nm to about 65 nm, or about 40 nm to about 60 nm. The ceria abrasive particles having a multimodal particle size distribution can be obtained by combining two different ceria abrasive particles each having a monomodal particle size distribution.

The ceria abrasive particles preferably are colloidally stable in the inventive polishing composition. The term colloid refers to the suspension of ceria abrasive particles in the aqueous carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]≤0.5). More preferably, the value of [B]−[T]/[C] is less than or equal to 0.3, and most preferably is less than or equal to 0.1.

The polishing composition can comprise any suitable concentration of ceria abrasive particles. If the polishing composition of the invention comprises too little ceria abrasive particles, the composition may not exhibit a sufficient removal rate. In contrast, if the polishing composition comprises too much ceria abrasive particles, then the polishing composition may exhibit undesirable polishing performance and/or may not be cost effective and/or may lack stability. The polishing composition comprises about 10 wt. % or less of the ceria abrasive particles, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less. Alternatively, or in addition, the polishing composition comprises about 0.001 wt. % or more of the ceria abrasive particles, for example, about 0.005 wt. % or more, about 0.01 wt. % or more, about 0.05 wt. % or more, or about 0.1 wt. % or more. Thus, the ceria abrasive particles can be present in the polishing composition at a concentration bounded by any two of the aforementioned endpoints. For example, the polishing composition can comprise about 0.001 wt. % to about 10 wt. % of the ceria abrasive particles, for example, about 0.001 wt. % to about 9 wt. %, about 0.005 wt. % to about 8 wt. %, about 0.01 wt. % to about 7 wt. %, about 0.05 wt. % to about 6 wt. %, about 0.1 wt. % to about 5 wt. %, about 0.5 wt. % to about 5 wt. %, about 0.5 wt. % to about 4 wt. %, about 1 wt. % to about 3 wt. %, or about 1.5 wt. % to about 2.5 wt. %. In an embodiment, the polishing composition can comprise, at the point-of-use, about 0.1 wt. % to about 1 wt. % or about 0.1 wt. % to about 0.5 wt. % of the ceria abrasive particles. In another embodiment, the polishing composition comprises, as a concentrate, between about 1 wt. % and about 3 wt. % (e.g., about 1.2 wt. % or about 1.6 wt. %) of the ceria abrasive particles.

The chemical-mechanical polishing composition comprises a cationic polymer. The cationic polymer can comprise any suitable cationic monomer capable of undergoing free radical polymerization and/or addition polymerization. In some embodiments, the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof. In certain embodiments, the cationic polymer comprises a cationic monomer selected from N-vinylimidazole, diallyldimethylammonium chloride (“DADMAC”), 2-(methacryloyloxy)-N,N,N-trimethylethanaminium chloride (“DMAEM.MCQ”), salts thereof, and combinations thereof. In other words, that cationic polymer can be polyvinylimidazole, polyDADMAC, polyMADQUAT (e.g., polyDMAEM.MCQ), salts thereof, or a combination thereof. In preferred embodiments, the polishing composition comprises polyMADQUAT and optionally an additional cationic polymer selected from polyvinylimidazole and polyDADMAC.

The polishing composition can comprise any suitable amount of the cationic polymer. The polishing composition can comprise about 10 ppm or more of the cationic polymer, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the cationic polymer, for example, about 800 ppm or less, about 600 ppm or less, about 400 ppm or less, about 200 ppm or less, or about 100 ppm or less. Thus, the polishing composition can comprise the cationic polymer in an amount bounded by any two of the aforementioned endpoints. For example, the polishing composition can comprise about 10 ppm to about 1000 ppm of the cationic polymer, e.g., about 10 ppm to about 800 ppm, about 10 ppm to about 600 ppm, about 10 ppm to about 400 ppm, about 10 ppm to about 200 ppm, about 10 ppm to about 100 ppm, about 25 ppm to about 1000 ppm, about 25 ppm to about 800 ppm, about 25 ppm to about 600 ppm, about 25 ppm to about 400 ppm, about 25 ppm to about 200 ppm, or about 25 ppm to about 100 ppm.

The cationic polymer can exist as any suitable structure type. For example, the cationic polymer can exist as an alternating polymer, a random polymer, a block polymer, a graft polymer, a linear polymer, a branched polymer, or a combination thereof. The cationic polymer can contain a single monomer unit, or any suitable number of different monomer units. For example, the cationic polymer can contain 2 different monomer units, 3 different monomer units, 4 different monomer units, 5 different monomer units, or 6 different monomer units. The cationic monomers of the cationic polymer can exist in any suitable concentration and any suitable proportion. In some embodiments, the cationic polymer further comprises a monomer selected from methacrylamide, acrylamide, and combinations thereof.

The cationic polymer can have any suitable weight average molecular weight. The cationic polymer can have a weight average molecular weight of about 150 g/mol or more, for example, about 300 g/mol or more, about 500 g/mol or more, about 600 g/mol or more, about 750 g/mol or more, about 1000 g/mol or more, about 1500 g/mol or more, about 2000 g/mol or more, about 2500 g/mol or more, about 3000 g/mol or more, about 3500 g/mol or more, about 4000 g/mol or more, about 4500 g/mol or more, about 5000 g/mol or more, about 5500 g/mol or more, about 6000 g/mol or more, about 6500 g/mol or more, about 7000 g/mol or more, or about 7500 g/mol or more. Alternatively, or in addition, the cationic polymer can have a weight average molecular weight of about 10000 g/mol or less, for example, about 9000 g/mol or less, about 8000 g/mol or less, about 7500 g/mol or less, about 7000 g/mol or less, about 6500 g/mol or less, about 6000 g/mol or less, about 5500 g/mol or less, about 5000 g/mol or less, about 4500 g/mol or less, about 4000 g/mol or less, about 3500 g/mol or less, about 3000 g/mol or less, about 2500 g/mol or less, or about 2000 g/mol or less. Thus, cationic polymer can have a weight average molecular weight bounded by any two of the aforementioned endpoints. For example, the cationic polymer can have a weight average molecular weight of about 150 g/mol to about 10000 g/mol, e.g., about 300 g/mol to about 9000 g/mol, about 500 g/mol to about 8000 g/mol, about 150 g/mol to about 7000 g/mol, about 150 g/mol to about 6000 g/mol, about 150 g/mol to about 5000 g/mol, about 150 g/mol to about 2000 g/mol, about 1000 g/mol to about 10000 g/mol, about 1000 g/mol to about 9000 g/mol, about 1000 g/mol to about 8000 g/mol, about 1000 g/mol to about 7000 g/mol, about 1000 g/mol to about 6000 g/mol, or about 1000 g/mol to about 5000 g/mol.

The chemical-mechanical polishing composition comprises a buffer. The buffer can be any suitable compound or combination of compounds capable of maintaining the pH of the polishing composition from about 3 to about 9 (e.g., a pH of about 6 to about 9). Generally, the buffer is an amine-based compound comprising from one to five nitrogen atoms. For example, the buffer can be a heterocyclic or heteroaromatic amine-based compound comprising from one to five nitrogen atoms. In some embodiments, the buffer comprises a heterocyclic or heteroaromatic amine selected from pyrrole, pyrrolidine, carbazole, isoindole, indole, pyrroline, indolizine, indoline, pyridine, piperidine, quinolizine isoquinoline, quinoline naphthyridine, imidazole, imidazoline, imidazolidine, tetrazole, triazole, benimidazole, purine, benzoxazole, benzthiazole, isothiazole, isoxazole, thiazole, oxazole, morpholine, thiomorpholine, pyrazole, pyrazoline, pteridine, triazine, pyrimidine, pyrazine, piperazine, indazole, pyridazine, and combinations thereof. In certain embodiments, the buffer is benzotriazole, 5-aminotetrazole, or a combination thereof.

The polishing composition can comprise any suitable amount of the buffer. The polishing composition can comprise about 25 ppm or more of the buffer, for example, about 50 ppm or more, about 100 ppm or more, or about 200 ppm or more. Alternatively, or in addition, the polishing composition can comprise about 5000 ppm or less of the buffer, for example, about 4000 ppm or less, about 3000 ppm or less, about 2000 ppm or less, or about 1000 ppm or less. Thus, the polishing composition can comprise the buffer in an amount bounded by any two of the aforementioned endpoints. For example, the polishing composition can comprise about 25 ppm to about 5000 ppm of the buffer, e.g., about 25 ppm to about 400 ppm, about 25 ppm to about 3000 ppm, about 25 ppm to about 2000 ppm, about 25 ppm to about 1000 ppm, about 50 ppm to about 5000 ppm, about 50 ppm to about 4000 ppm, about 50 ppm to about 3000 ppm, about 50 ppm to about 2000 ppm, about 50 ppm to about 1000 ppm, about 100 ppm to about 5000 ppm, or about 100 ppm to about 1000 ppm.

In some embodiments, the polishing composition further comprises a nonionic polymer. Thus, in some aspects, the invention provides a chemical-mechanical polishing composition comprising, consisting essentially of, or consisting of: (a) ceria abrasive particles; (b) a cationic polymer; (c) a buffer; (d) a nonionic polymer; and (e) water, wherein the polishing composition has a pH of about 6 to about 9.

The nonionic polymer can be any suitable polymer without a cationic or anionic charge at a pH of about 6 to about 9 (e.g., a pH of about 7 to about 9). In some embodiments, the nonionic polymer is selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharide, and combinations thereof. In certain embodiments, the nonionic polymer is polyvinylpyrrolidone, polyalkylene glycol (e.g., polyethylene glycol (PEG) or polypropylene oxide (PPO)), a polyethylene oxide/polypropylene oxide copolymer, or a combination thereof. In preferred embodiments, the nonionic polymer is polyethylene glycol (PEG).

The non-ionic polymer can have any suitable weight average molecular weight. The non-ionic polymer can have a weight average molecular weight of about 400 g/mol or more, for example, about 500 g/mol or more, about 600 g/mol or more, about 750 g/mol or more, about 1000 g/mol or more, about 1500 g/mol or more, about 2000 g/mol or more, about 2500 g/mol or more, about 3000 g/mol or more, about 3500 g/mol or more, about 4000 g/mol or more, about 4500 g/mol or more, about 5000 g/mol or more, about 5500 g/mol or more, about 6000 g/mol or more, about 6500 g/mol or more, about 7000 g/mol or more, or about 7500 g/mol or more. Alternatively, or in addition, the non-ionic polymer can have a weight average molecular weight of about 10000 g/mol or less, for example, about 9000 g/mol or less, about 8000 g/mol or less, about 7500 g/mol or less, about 7000 g/mol or less, about 6500 g/mol or less, about 6000 g/mol or less, about 5500 g/mol or less, about 5000 g/mol or less, about 4500 g/mol or less, about 4000 g/mol or less, about 3500 g/mol or less, about 3000 g/mol or less, about 2500 g/mol or less, or about 2000 g/mol or less. Thus, the non-ionic polymer can have a weight average molecular weight bounded by any two of the aforementioned endpoints. For example, the non-ionic polymer can have a weight average molecular weight of about 400 g/mol to about 10000 g/mol, e.g., about 400 g/mol to about 9000 g/mol, about 400 g/mol to about 8000 g/mol, about 400 g/mol to about 7000 g/mol, about 400 g/mol to about 6000 g/mol, about 400 g/mol to about 5000 g/mol, about 1000 g/mol to about 10000 g/mol, about 1000 g/mol to about 9000 g/mol, about 1000 g/mol to about 8000 g/mol, about 1000 g/mol to about 7000 g/mol, about 1000 g/mol to about 6000 g/mol, or about 1000 g/mol to about 5000 g/mol.

The polishing composition can comprise any suitable amount of the nonionic polymer, when present. The polishing composition can comprise about 25 ppm or more of the nonionic polymer, for example, about 50 ppm or more, about 100 ppm or more, or about 200 ppm or more. Alternatively, or in addition, the polishing composition can comprise about 5000 ppm or less of the nonionic polymer, for example, about 4000 ppm or less, about 3000 ppm or less, about 2000 ppm or less, or about 1000 ppm or less. Thus, the polishing composition can comprise the nonionic polymer in an amount bounded by any two of the aforementioned endpoints. For example, the polishing composition can comprise about 25 ppm to about 5000 ppm of the nonionic polymer, e.g., about 25 ppm to about 400 ppm, about 25 ppm to about 3000 ppm, about 25 ppm to about 2000 ppm, about 25 ppm to about 1000 ppm, about 50 ppm to about 5000 ppm, about 50 ppm to about 4000 ppm, about 50 ppm to about 3000 ppm, about 50 ppm to about 2000 ppm, about 50 ppm to about 1000 ppm, about 100 ppm to about 5000 ppm, or about 100 ppm to about 1000 ppm.

In some embodiments, the polishing composition further comprises a cationic surfactant. Thus, in some aspects, the invention provides a chemical-mechanical polishing composition comprising, consisting essentially of, or consisting of: (a) ceria abrasive particles; (b) a cationic polymer; (c) a buffer; (d) a cationic surfactant; and (e) water, wherein the polishing composition has a pH of about 6 to about 9.

The cationic surfactant can be any suitable surfactant that carries a cationic charge at a neutral pH (i.e., a pH of about 7). Generally, the cationic surfactant comprises a quaternary ammonium salt. For example, the cationic surfactant can be an alkyl ammonium salt such as an alkyl ammonium p-toluenesulfonate or an alkyl ammonium chloride. In certain embodiments, the cationic surfactant is selected from N,N,N′,N′,N′-pentamethyl-N-tallow alkyl-1,3-propanediammonium dichloride, (oxydi-2,1-ethanediyl)bis(coco alkyl)dimethyl ammonium dichlorides, salts thereof, and combinations thereof.

The polishing composition can comprise any suitable amount of the cationic surfactant, when present. The polishing composition can comprise about 10 ppm or more of the cationic surfactant, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the cationic surfactant, for example, about 800 ppm or less, about 600 ppm or less, about 400 ppm or less, about 200 ppm or less, or about 100 ppm or less. Thus, the polishing composition can comprise the cationic surfactant in an amount bounded by any two of the aforementioned endpoints. For example, the polishing composition can comprise about 10 ppm to about 1000 ppm of the cationic surfactant, e.g., about 10 ppm to about 800 ppm, about 10 ppm to about 600 ppm, about 10 ppm to about 400 ppm, about 10 ppm to about 200 ppm, about 10 ppm to about 100 ppm, about 25 ppm to about 1000 ppm, about 25 ppm to about 800 ppm, about 25 ppm to about 600 ppm, about 25 ppm to about 400 ppm, about 25 ppm to about 200 ppm, or about 25 ppm to about 100 ppm.

In some embodiments, the polishing composition further comprises a self-stopping agent. Thus, in some aspects, the invention provides a chemical-mechanical polishing composition comprising, consisting essentially of, or consisting of: (a) ceria abrasive particles; (b) a cationic polymer; (c) a buffer; (d) a self-stopping agent; and (e) water, wherein the polishing composition has a pH of about 6 to about 9.

The self-stopping agent can be any suitable compound that is capable of reducing the removal rate of one or more of silicon oxide, silicon nitride, and polysilicon. In some embodiments, the self-stopping agent is of formula (I):

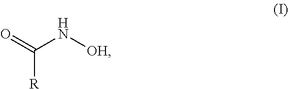

wherein R is selected from hydrogen, alkyl, heteroalkyl, cycloalkyl, heterocycloalkyl, aryl, and heteroaryl, each of which may be substituted or unsubstituted.

As used herein, the term “alkyl” refers to a straight or branched, saturated or unsaturated, aliphatic radical having the number of carbon atoms indicated. Alkyl can include any number of carbons, such as C₁₋₂, C₁₋₃, C₁₋₄, C₁₋₅, C₁₋₆, C₁₋₇, C₁₋₈, C₁₋₉, C₁₋₁₀, C₂₋₃, C₂₋₄, C₂₋₅, C₂₋₆, C₃₋₄, C₃₋₅, C₃₋₆, C₄₋₅, C₄₋₆ and C₅₋₆. For example, C₁₋₆ alkyl includes, but is not limited to, methyl, ethyl, propyl, isopropyl, butyl, isobutyl, sec-butyl, tert-butyl, pentyl, isopentyl, hexyl, etc. Alkyl can also refer to alkyl groups having up to 30 carbons atoms, such as, but not limited to heptyl, octyl, nonyl, decyl, etc. Alkyl groups can be substituted or unsubstituted. “Substituted alkyl” groups can be substituted with one or more groups selected from halo, hydroxy, amino, oxo (═O), alkylamino, amido, acyl, nitro, cyano, and alkoxy.

As used herein, the term “heteroalkyl” refers to an alkyl group as described herein, wherein one or more carbon atoms are optionally and independently replaced with a heteroatom selected from N, O, and S.

As used herein, the term “cycloalkyl” refers to a saturated or partially unsaturated, monocyclic, fused bicyclic, or bridged polycyclic ring assembly containing from 3 to 12 ring atoms, or the number of atoms indicated. Cycloalkyl groups can include any number of carbons, such as C₃₋₆, C₄₋₆, C₅₋₆, C₃₋₈, C₄₋₈, C₅₋₈, C₆₋₈, C₃₋₉, C₃₋₁₀, C₃₋₁₁, and C₃₋₁₂. Saturated monocyclic carbocyclic rings include, for example, cyclopropyl, cyclobutyl, cyclopentyl, cyclohexyl, and cyclooctyl. Saturated bicyclic and polycyclic carbocyclic rings include, for example, norbornane, [2.2.2] bicyclooctane, decahydronaphthalene and adamantane. Carbocyclic groups can also be partially unsaturated, having one or more double or triple bonds in the ring. Representative carbocyclic groups that are partially unsaturated include, but are not limited to, cyclobutene, cyclopentene, cyclohexene, cyclohexadiene (1,3- and 1,4-isomers), cycloheptene, cycloheptadiene, cyclooctene, cyclooctadiene (1,3-, 1,4- and 1,5-isomers), norbornene, and norbornadiene.

As used herein, the term “heterocycloalkyl” refers to a cycloalkyl group as described herein, wherein one or more carbon atoms are optionally and independently replaced with a heteroatom selected from N, O, and S.

As used herein, the term “aryl” refers to an aromatic ring system having any suitable number of ring atoms and any suitable number of rings. Aryl groups can include any suitable number of ring atoms, such as, 6, 7, 8, 9, 10, 11, 12, 13, 14, 15 or 16 ring atoms, as well as from 6 to 10, 6 to 12, or 6 to 14 ring members. Aryl groups can be monocyclic, fused to form bicyclic or tricyclic groups, or linked by a bond to form a biaryl group. Representative aryl groups include phenyl, naphthyl and biphenyl. Other aryl groups include benzyl, having a methylene linking group. Some aryl groups have from 6 to 12 ring members, such as phenyl, naphthyl or biphenyl. Other aryl groups have from 6 to 10 ring members, such as phenyl or naphthyl.

As used herein, the term “heteroaryl” refers to an aryl group as described herein, wherein one or more carbon atoms are optionally and independently replaced with a heteroatom selected from N, O, and S.

In certain embodiments, the self-stopping agent is selected from hydroxamic acid, acetohydroxamic acid, benzhydroxamic acid, salicylhydroxamic acid, and combinations thereof.

The polishing composition can comprise any suitable amount of the self-stopping agent, when present. The polishing composition can comprise about 10 ppm or more of the self-stopping agent, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the self-stopping agent, for example, about 800 ppm or less, about 600 ppm or less, about 400 ppm or less, about 200 ppm or less, or about 100 ppm or less. Thus, the polishing composition can comprise the self-stopping agent in an amount bounded by any two of the aforementioned endpoints. For example, the polishing composition can comprise about 10 ppm to about 1000 ppm of the self-stopping agent, e.g., about 10 ppm to about 800 ppm, about 10 ppm to about 600 ppm, about 10 ppm to about 400 ppm, about 10 ppm to about 200 ppm, about 10 ppm to about 100 ppm, about 25 ppm to about 1000 ppm, about 25 ppm to about 800 ppm, about 25 ppm to about 600 ppm, about 25 ppm to about 400 ppm, about 25 ppm to about 200 ppm, or about 25 ppm to about 100 ppm.

The chemical-mechanical polishing composition can comprise one or more compounds capable of adjusting (i.e., that adjust) the conductivity of the polishing composition (i.e., pH adjusting compounds). The conductivity of the polishing composition can be adjusted using any suitable conductivity adjust described herein. Typically, the chemical-mechanical polishing composition has a conductivity of at least 170 μS/cm at the point-of-use (e.g., at least 200 μS/cm, at least 250 μS/cm, at least 300 μS/cm, at least 350 μS/cm, at least 400 μS/cm, at least 450 μS/cm, or at least 500 μS/cm). For example, the chemical-mechanical polishing composition can have a conductivity of from 170 μS/cm to 2000 μS/cm, from 350 μS/cm to 2000 μS/cm, or from 500 μS/cm to 2000 μS/cm. Preferably, the chemical-mechanical polishing composition has a conductivity of from 350 μS/cm to 2000 μS/cm at the point-of-use.

Thus, in some embodiments, the polishing composition further comprises a conductivity adjust. Thus, in some aspects, the invention provides a chemical-mechanical polishing composition comprising, consisting essentially of, or consisting of: (a) ceria abrasive particles; (b) a cationic polymer; (c) a buffer; (d) a conductivity adjust; and (e) water, wherein the polishing composition has a pH of about 6 to about 9.

As used herein, the term “conductivity adjust” refers to any small molecule salt capable of adjusting the conductivity of the polishing composition. In some embodiments, the conductivity adjust is selected from an ammonium salt, a potassium salt, and a combination thereof. The conductivity adjust can have any suitable counterion. For example, the conductivity adjust can have a counterion selected from a nitrate, an acetate, a halide, a phosphate, and a sulfate. Thus, in some embodiments, the conductivity adjust is selected from an ammonium nitrate, an ammonium acetate, an ammonium halide, an ammonium phosphate, an ammonium sulfate, a potassium nitrate, a potassium acetate, a potassium halide, a potassium phosphate, a potassium sulfate, or a combination thereof.

In some embodiments, the conductivity adjust is selected from ammonium nitrate, ammonium chloride, ammonium bromide, ammonium acetate, potassium nitrate, potassium chloride, potassium bromide, potassium acetate, diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof. In an embodiment, the conductivity adjust is selected from diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof. In another embodiment, the conductivity adjust is selected from ammonium nitrate, ammonium chloride, ammonium bromide, ammonium acetate, potassium nitrate, potassium chloride, potassium bromide, potassium acetate, and combinations thereof. In certain embodiments, the conductivity adjust is selected from ammonium nitrate, potassium nitrate, diallyldimethylammonium chloride, tetrabutylammonium bromide, tetramethylammonium bromide, and combinations thereof.

The polishing composition can comprise any suitable amount of the conductivity adjust, when present. The polishing composition can comprise about 25 ppm or more of the conductivity adjust, for example, about 50 ppm or more, about 100 ppm or more, or about 200 ppm or more. Alternatively, or in addition, the polishing composition can comprise about 5000 ppm or less of the conductivity adjust, for example, about 4000 ppm or less, about 3000 ppm or less, about 2000 ppm or less, or about 1000 ppm or less. Thus, the polishing composition can comprise the conductivity adjust in an amount bounded by any two of the aforementioned endpoints. For example, the polishing composition can comprise about 25 ppm to about 5000 ppm of the conductivity adjust, e.g., about 25 ppm to about 400 ppm, about 25 ppm to about 3000 ppm, about 25 ppm to about 2000 ppm, about 25 ppm to about 1000 ppm, about 50 ppm to about 5000 ppm, about 50 ppm to about 4000 ppm, about 50 ppm to about 3000 ppm, about 50 ppm to about 2000 ppm, about 50 ppm to about 1000 ppm, about 100 ppm to about 5000 ppm, or about 100 ppm to about 1000 ppm.

In some aspects, the invention provides a chemical-mechanical polishing composition comprising, consisting essentially of, or consisting of: (a) ceria abrasive particles; (b) a cationic polymer; (c) a buffer; (d) a nonionic polymer; (e) a cationic surfactant; and (0 water, wherein the polishing composition has a pH of about 6 to about 9.

In some aspects, the invention provides a chemical-mechanical polishing composition comprising, consisting essentially of, or consisting of: (a) ceria abrasive particles; (b) a cationic polymer; (c) a buffer; (d) a cationic surfactant; (e) a self-stopping agent; and (0 water, wherein the polishing composition has a pH of about 6 to about 9.

In some aspects, the invention provides a chemical-mechanical polishing composition comprising, consisting essentially of, or consisting of: (a) ceria abrasive particles; (b) a cationic polymer; (c) a buffer; (d) a conductivity adjust; (e) a cationic surfactant; and (0 water, wherein the polishing composition has a pH of about 6 to about 9.

In some aspects, the invention provides a chemical-mechanical polishing composition comprising, consisting essentially of, or consisting of: (a) ceria abrasive particles; (b) a cationic polymer; (c) a buffer; (d) a conductivity adjust; (e) a nonionic polymer; and (0 water, wherein the polishing composition has a pH of about 6 to about 9.

The polishing composition comprises an aqueous carrier. The aqueous carrier comprises water (e.g., deionized water) and may contain one or more water-miscible organic solvents. Examples of organic solvents that can be used include alcohols such as propenyl alcohol, isopropyl alcohol, ethanol, 1-propanol, methanol, 1-hexanol, and the like; aldehydes such as acetylaldehyde and the like; ketones such as acetone, diacetone alcohol, methyl ethyl ketone, and the like; esters such as ethyl formate, propyl formate, ethyl acetate, methyl acetate, methyl lactate, butyl lactate, ethyl lactate, and the like; ethers including sulfoxides such as dimethyl sulfoxide (DMSO), tetrahydrofuran, dioxane, diglyme, and the like; amides such as N, N-dimethylformamide, dimethylimidazolidinone, N-methylpyrrolidone, and the like; polyhydric alcohols and derivatives of the same such as ethylene glycol, glycerol, diethylene glycol, diethylene glycol monomethyl ether, and the like; and nitrogen-containing organic compounds such as acetonitrile, amylamine, isopropylamine, imidazole, dimethylamine, and the like. Preferably, the aqueous carrier is water alone, i.e., without the presence of an organic solvent.

The chemical-mechanical polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition. Typically, the chemical-mechanical polishing composition has a pH of about 6 to about 9 at the point-of-use (e.g., about 6 to about 8, of about 6 to about 7, of about 7 to about 9, of about 8 to about 9, of about 6.5 to about 8.5, of about 6.5 to about 7.5, or of about 7.5 to about 8.5). Preferably, the chemical-mechanical polishing composition has a pH of about 6 to about 9 or about 7 to about 8 at the point-of-use.

The compound capable of adjusting the pH can be selected from the group consisting of ammonium salts, alkali metal salts, carboxylic acids, alkali metal hydroxides, alkali metal carbonates, alkali metal bicarbonates, borates, and mixtures thereof.

The chemical-mechanical polishing composition optionally further comprises one or more additives. Illustrative additives include conditioners, acids (e.g., sulfonic acids), complexing agents, chelating agents, biocides, scale inhibitors, and dispersants.

A biocide, when present, can be any suitable biocide and can be present in the polishing composition in any suitable amount. A suitable biocide is an isothiazolinone biocide. The biocide can be present in the polishing composition at a concentration of about 1 to about 750 ppm, preferably about 20 to about 200 ppm.

The polishing composition can be produced by any suitable technique, many of which are known to those skilled in the art. The polishing composition can be prepared in a batch or continuous process. Generally, the polishing composition is prepared by combining the components of the polishing composition. The term “component” as used herein includes individual ingredients (e.g., ceria abrasive particles, cationic polymer, buffer, optional conductivity adjust, optional cationic surfactant, optional nonionic polymer, optional self-stopping agent, and/or any other optional additive) as well as any combination of ingredients (e.g., ceria abrasive particles, cationic polymer, buffer, optional conductivity adjust, optional cationic surfactant, optional nonionic polymer, optional self-stopping agent, and/or any other optional additive, etc.).

For example, the polishing composition can be prepared by (i) providing all or a portion of the liquid carrier, (ii) dispersing the ceria abrasive particles, cationic polymer, buffer, optional conductivity adjust, optional cationic surfactant, optional nonionic polymer, optional self-stopping agent, and/or any other optional additive, using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., cationic polymer, buffer, optional conductivity adjust, optional cationic surfactant, optional nonionic polymer, optional self-stopping agent, and/or any other optional additive) in a ceria abrasive slurry, (ii) providing one or more components in an additive solution (e.g., cationic polymer, buffer, optional conductivity adjust, optional cationic surfactant, optional nonionic polymer, optional self-stopping agent, and/or any other optional additive), (iii) combining the ceria abrasive slurry and the additive solution to form a mixture, (iv) optionally adding suitable amounts of any other optional additives to the mixture, and (v) adjusting the pH of the mixture as appropriate.

The polishing composition can be supplied as a one-package system comprising ceria abrasive particles, cationic polymer, buffer, optional conductivity adjust, optional cationic surfactant, optional nonionic polymer, optional self-stopping agent, any other optional additive, and water. Alternatively, the polishing composition of the invention can be supplied as a two-package system comprising a ceria abrasive slurry in a first package and an additive solution in a second package, wherein the ceria abrasive slurry consists essentially of, or consists of, ceria abrasive particles, and water, and wherein the additive solution consists essentially of, or consists of, cationic polymer, buffer, optional conductivity adjust, optional cationic surfactant, optional nonionic polymer, optional self-stopping agent, and/or any other optional additive. The two-package system allows for the adjustment of polishing composition characteristics by changing the blending ratio of the two packages, i.e., the ceria abrasive slurry and the additive solution.

Various methods can be employed to utilize such a two-package polishing system. For example, the ceria abrasive slurry and additive solution can be delivered to the polishing table by different pipes that are joined and connected at the outlet of supply piping. The ceria abrasive slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the ceria abrasive particles, cationic polymer, buffer, optional conductivity adjust, optional cationic surfactant, optional nonionic polymer, optional self-stopping agent, and/or any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that the ceria abrasive particles, cationic polymer, buffer, optional conductivity adjust, optional cationic surfactant, optional nonionic polymer, optional self-stopping agent, and/or any other optional additive are at least partially or fully dissolved in the concentrate.

The invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; and (d) water, wherein the polishing composition has a pH of about 3 to about 9, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of a low dielectric material. Suitable substrates include wafers used in the semiconductor industry. The wafers typically comprise or consist of, for example, a metal, metal oxide, metal nitride, metal composite, metal alloy, a low dielectric material, or combinations thereof. The method of the invention is particularly useful for polishing substrates comprising silicon oxide, silicon nitride, and/or polysilicon, e.g., any one or all of the aforementioned materials. In some embodiments, the substrate comprises silicon oxide, silicon nitride, and polysilicon on a surface of the substrate, and at least a portion of the silicon oxide, silicon nitride, and polysilicon on a surface of the substrate is abraded to polish the substrate.

In certain embodiments, the substrate comprises silicon oxide, silicon nitride, and polysilicon. The polysilicon can be any suitable polysilicon, many of which are known in the art. The polysilicon can have any suitable phase, and can be amorphous, crystalline, or a combination thereof. The silicon nitride can be any suitable silicon nitride, many of which are known in the art. The silicon nitride can have any suitable phase, and can be amorphous, crystalline, or a combination thereof. The silicon oxide similarly can be any suitable silicon oxide, many of which are known in the art. Suitable types of silicon oxide include but are not limited to borophosphosilicate glass (BPSG), high density plasma (HDP) oxides and/or plasma-enhanced tetraethyl ortho silicate (PETEOS) and/or tetraethyl orthosilicate (TEOS), thermal oxide, and undoped silicate glass.

The chemical-mechanical polishing composition of the invention can be tailored to provide effective polishing at the desired polishing ranges selective to specific thin layer materials, while at the same time minimizing surface imperfections, defects, corrosion, erosion and the removal of stop layers. The selectivity can be controlled, to some extent, by altering the relative concentrations of the components of the polishing composition.

When desirable, the chemical-mechanical polishing composition of the invention can provide nonselective chemical-mechanical polishing of a substrate comprising silicon oxide, silicon nitride, and polysilicon. In other words, the polishing composition can provide approximately a 1:1:1 ratio in relative removal rates of silicon oxide, silicon nitride, and polysilicon. In that regard, the method can provide removal rates of silicon oxide, silicon nitride, and polysilicon where the silicon oxide removal rate, the silicon nitride removal rate, and the polysilicon removal rate have an overall average removal rate (i.e., the sum of the silicon oxide removal rate, the silicon nitride removal rate, and the polysilicon removal rate divided by three), and each of the silicon oxide removal rate, the silicon nitride removal rate, and the polysilicon removal rate are within 20% of the overall average removal rate. In some embodiments, the method can provide removal rates of silicon oxide, silicon nitride, and polysilicon where the silicon oxide removal rate, the silicon nitride removal rate, and the polysilicon removal rate have an overall average removal rate, and each of the silicon oxide removal rate, the silicon nitride removal rate, and the polysilicon removal rate are within 15% of the overall average removal rate. In certain embodiments, the method can provide removal rates of silicon oxide, silicon nitride, and polysilicon where the silicon oxide removal rate, the silicon nitride removal rate, and the polysilicon removal rate have an overall average removal rate, and each of the silicon oxide removal rate, the silicon nitride removal rate, and the polysilicon removal rate are within 10% of the overall average removal rate.

Without wishing to be bound by any particular theory, it is believed that adding a nonionic polymer alone or in combination with a cationic surfactant can help to make the polishing composition nonselective, i.e., help maintain similar removal rates for each of silicon oxide, silicon nitride, and polysilicon. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a nonionic polymer; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

Similarly, in certain aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a cationic surfactant; (e) a nonionic polymer; and (0 water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

Without wishing to be bound by any particular theory, it is also believed that adding a conductivity adjust (e.g., ammonium nitrate or potassium nitrate) alone or in combination with a nonionic polymer and/or a cationic surfactant can help to make the polishing composition nonselective, i.e., help maintain similar removal rates for each of silicon oxide, silicon nitride, and polysilicon. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a conductivity adjust; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

When desirable, the chemical-mechanical polishing composition of the invention can provide selective chemical-mechanical polishing of a substrate comprising silicon oxide, silicon nitride, and polysilicon to selectively remove silicon oxide at an reduced rate relative to silicon nitride and polysilicon. In that regard, the method can provide removal rates of silicon oxide, silicon nitride, and polysilicon where the silicon oxide removal rate, the silicon nitride removal rate, and the polysilicon removal rate have an overall average removal rate (i.e., the sum of the silicon oxide removal rate, the silicon nitride removal rate, and the polysilicon removal rate divided by three), and the silicon oxide removal rate is at least 50% less than the overall average removal rate. In some embodiments, the method can provide removal rates of silicon oxide, silicon nitride, and polysilicon where the silicon oxide removal rate, the silicon nitride removal rate, and the polysilicon removal rate have an overall average removal rate, and the silicon oxide removal rate is at least 60% less than the overall average removal rate. In certain embodiments, the method can provide removal rates of silicon oxide, silicon nitride, and polysilicon where the silicon oxide removal rate, the silicon nitride removal rate, and the polysilicon removal rate have an overall average removal rate, and the silicon oxide removal rate is at least 70% less than the overall average removal rate.

Without wishing to be bound by any particular theory, it is believed that (i) adding an additional cationic polymer (e.g., polyMADQUAT, polyDADMAC, and/or polyvinylimidazole) and/or (ii) adding a cationic surfactant can selectively remove silicon oxide at a reduced rate relative to silicon nitride and polysilicon. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a cationic surfactant; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate. Similarly, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) two or more cationic polymers; (c) a buffer; and (d) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

Without wishing to be bound by any particular theory, it is also believed that adding a conductivity adjust (e.g., diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, or combinations thereof) can selectively remove silicon oxide at a reduced rate relative to silicon nitride and polysilicon. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a conductivity adjust; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

When desirable, the chemical-mechanical polishing composition of the invention can provide selective chemical-mechanical polishing of a substrate comprising silicon oxide, silicon nitride, and polysilicon to selectively remove silicon nitride at an reduced rate relative to silicon oxide and polysilicon. In that regard, the method can provide removal rates of silicon oxide, silicon nitride, and polysilicon where the silicon oxide removal rate, the silicon nitride removal rate, and the polysilicon removal rate have an overall average removal rate (i.e., the sum of the silicon oxide removal rate, the silicon nitride removal rate, and the polysilicon removal rate divided by three), and the silicon nitride removal rate is at least 50% less than the overall average removal rate. In some embodiments, the method can provide removal rates of silicon oxide, silicon nitride, and polysilicon where the silicon oxide removal rate, the silicon nitride removal rate, and the polysilicon removal rate have an overall average removal rate, and the silicon nitride removal rate is at least 60% less than the overall average removal rate. In certain embodiments, the method can provide removal rates of silicon oxide, silicon nitride, and polysilicon where the silicon oxide removal rate, the silicon nitride removal rate, and the polysilicon removal rate have an overall average removal rate, and the silicon nitride removal rate is at least 70% less than the overall average removal rate.

Without wishing to be bound by any particular theory, it is believed that adding a self-stopping agent can selectively remove silicon nitride at a reduced rate relative to silicon oxide and polysilicon. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a self-stopping agent; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

When desirable, the chemical-mechanical polishing composition of the invention can provide selective chemical-mechanical polishing of a substrate comprising silicon oxide, silicon nitride, and polysilicon to selectively remove polysilicon at an reduced rate relative to silicon oxide and silicon nitride. In that regard, the method can provide removal rates of silicon oxide, silicon nitride, and polysilicon where the silicon oxide removal rate, the silicon nitride removal rate, and the polysilicon removal rate have an overall average removal rate (i.e., the sum of the silicon oxide removal rate, the silicon nitride removal rate, and the polysilicon removal rate divided by three), and the polysilicon removal rate is at least 50% less than the overall average removal rate. In some embodiments, the method can provide removal rates of silicon oxide, silicon nitride, and polysilicon where the silicon oxide removal rate, the silicon nitride removal rate, and the polysilicon removal rate have an overall average removal rate, and the polysilicon removal rate is at least 60% less than the overall average removal rate. In certain embodiments, the method can provide removal rates of silicon oxide, silicon nitride, and polysilicon where the silicon oxide removal rate, the silicon nitride removal rate, and the polysilicon removal rate have an overall average removal rate, and the polysilicon removal rate is at least 70% less than the overall average removal rate.

Without wishing to be bound by any particular theory, it is believed that adding a nonionic polymer can selectively remove polysilicon at a reduced rate relative to silicon oxide and silicon nitride. Thus, in some aspects, the invention further provides a method of chemically-mechanically polishing a substrate comprising, consisting essentially of, or consisting of: (i) providing a substrate, (ii) providing a polishing pad, (iii) providing a chemical-mechanical polishing composition comprising: (a) ceria abrasive particles; (b) a cationic polymer; (c) a buffer; (d) a nonionic polymer; and (e) water, wherein the polishing composition has a pH of about 6 to about 9 (e.g., a pH of about 7 to about 9), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

When desirable, the chemical-mechanical polishing composition of the invention can provide selective chemical-mechanical polishing of a substrate comprising silicon oxide, silicon nitride, and polysilicon to selectively remove each of silicon oxide and silicon nitride at a reduced rate relative to polysilicon. In that regard, the method can provide removal rates of silicon oxide, silicon nitride, and polysilicon where the silicon oxide removal rate, the silicon nitride removal rate, and the polysilicon removal rate have an overall average removal rate (i.e., the sum of the silicon oxide removal rate, the silicon nitride removal rate, and the polysilicon removal rate divided by three), each of the silicon oxide removal rate and the silicon nitride removal rate is at least 50% less than the overall average removal rate. In some embodiments, the method can provide removal rates of silicon oxide, silicon nitride, and polysilicon where the silicon oxide removal rate, the silicon nitride removal rate, and the polysilicon removal rate have an overall average removal rate, each of the silicon oxide removal rate and the silicon nitride removal rate is at least 60% less than the overall average removal rate. In certain embodiments, the method can provide removal rates of silicon oxide, silicon nitride, and polysilicon where the silicon oxide removal rate, the silicon nitride removal rate, and the polysilicon removal rate have an overall average removal rate, each of the silicon oxide removal rate and the silicon nitride removal rate is at least 70% less than the overall average removal rate.

The polishing composition of the invention desirably exhibits low particle defects when polishing a substrate, as determined by suitable techniques. In a preferred embodiment, the chemical-mechanical polishing composition of the invention comprises a wet-process ceria which contributes to the low defectivity. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

A substrate, especially silicon comprising silicon oxide, silicon nitride, and/or polysilicon, polished with the inventive polishing composition desirably has a DCN value of about 20000 counts or less, for example, about 17500 counts or less, about 15000 counts or less, about 12500 counts or less, about 3500 counts or less, about 3000 counts or less, about 2500 counts or less, about 2000 counts or less, about 1500 counts or less, or about 1000 counts or less. Preferably substrates polished in accordance with an embodiment of the invention have a DCN value of about 750 counts or less, for example, about 500 counts or less, about 250 counts or less, about 125 counts or less, or even about 100 counts or less.

Alternatively, or in addition, a substrate polished with the chemical-mechanical polishing composition of the invention desirably exhibits low scratches as determined by suitable techniques. For example, silicon wafers polished in accordance with an embodiment of the invention desirably have about 250 scratches or less, or about 125 scratches or less, as determined by any suitable method known in the art such as, e.g., laser light scattering techniques.

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof. Soft polyurethane polishing pads are particularly useful in conjunction with the inventive polishing method. Typical pads include but are not limited to SURFIN™ 000, SURFIN™ SSW1, SPM3100 Eminess Technologies), POLITEX™ commercially available from Dow Chemical Company (Newark, Del.), and POLYPAS™ 27 commercially available from Fujibo (Osaka, JP), and EPIC™ D100 pads or NEXPLANAR™ E6088 commercially available from Cabot Microelectronics (Aurora, Ill.). A preferred polishing pad is the rigid, microporous polyurethane pad (IC1010 ™) commercially available from Dow Chemical.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511, 5,643,046, 5,658,183, 5,730,642, 5,838,447, 5,872,633, 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

### EMBODIMENTS

(1) In embodiment (1) is presented a chemical-mechanical polishing composition comprising:
(a) ceria abrasive particles;
(b) a cationic polymer;
(c) a buffer; and
(d) water,
   wherein the polishing composition has a pH of about 6 to about 9.

(2) In embodiment (2) is presented the polishing composition of embodiment (1), wherein the polishing composition comprises about 0.001 wt. % to about 10 wt. % of the ceria abrasive particles.

(3) In embodiment (3) is presented the polishing composition of embodiment (1) or embodiment (2), wherein the polishing composition comprises about 0.05 wt. % to about 5 wt. % of the ceria abrasive particles.

(4) In embodiment (4) is presented the polishing composition of any one of embodiments (1)-(3), wherein the polishing composition has a pH of about 7 to about 9.

(5) In embodiment (5) is presented the polishing composition of any one of embodiments (1)-(4), wherein the polishing composition has a pH of about 7 to about 8.

(6) In embodiment (6) is presented the polishing composition of any one of embodiments (1)-(5), wherein the polishing composition further comprises a nonionic polymer selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharide, and combinations thereof.

(7) In embodiment (7) is presented the polishing composition of embodiment (6), wherein the nonionic polymer is polyvinylpyrrolidone.

(8) In embodiment (8) is presented the polishing composition of embodiment (6), wherein the nonionic polymer is a polyalkylene glycol.

(9) In embodiment (9) is presented the polishing composition of embodiment (6), wherein the nonionic polymer is a polyethylene oxide/polypropylene oxide copolymer.

(10) In embodiment (10) is presented the polishing composition of any one of embodiments (1)-(9), wherein the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof.

(11) In embodiment (11) is presented the polishing composition of embodiment (10), wherein the cationic monomer is selected from N-vinylimidazole, diallyldimethylammonium chloride (“DADMAC”), 2-(methacryloyloxy)-N,N,N-trimethylethanaminium chloride (“DMAEM.MCQ”), salts thereof, and combinations thereof.

(12) In embodiment (12) is presented the polishing composition of any one of embodiments (1)-(11), wherein the buffer is an amine-based compound comprising from one to five nitrogen atoms.

(13) In embodiment (13) is presented the polishing composition of any one of embodiments (1)-(12), wherein the buffer is a heterocyclic or heteroaromatic amine-based compound comprising from one to five nitrogen atoms.

(14) In embodiment (14) is presented the polishing composition of any one of embodiments (1)-(13), wherein the buffer comprises a heterocyclic or heteroaromatic amine selected from pyrrole, pyrrolidine, carbazole, isoindole, indole, pyrroline, indolizine, indoline, pyridine, piperidine, quinolizine isoquinoline, quinoline naphthyridine, imidazole, imidazoline, imidazolidine, tetrazole, triazole, benimidazole, purine, benzoxazole, benzthiazole, isothiazole, isoxazole, thiazole, oxazole, morpholine, thiomorpholine, pyrazole, pyrazoline, pteridine, triazine, pyrimidine, pyrazine, piperazine, indazole, pyridazine, and combinations thereof.

(15) In embodiment (15) is presented the polishing composition of any one of embodiments (1)-(14), where the buffer is benzotriazole, 5-aminotetrazole, or a combination thereof.

(16) In embodiment (16) is presented the polishing composition of any one of embodiments (1)-(15), wherein the polishing composition further comprises a cationic surfactant.

(17) In embodiment (17) is presented the polishing composition of embodiment (16), wherein the cationic surfactant comprises a quaternary ammonium salt.

(18) In embodiment (18) is presented the polishing composition of embodiment (16) or embodiment (17), wherein the cationic surfactant is selected from N,N,N′,N′,N′-pentamethyl-N-tallow alkyl-1,3-propanediammonium dichloride, (oxydi-2,1-ethanediyl)bis(coco alkyl)dimethyl ammonium dichlorides, salts thereof, and combinations thereof.

(19) In embodiment (19) is presented the polishing composition of any one of embodiments (1)-(18), wherein the polishing composition further comprises a self-stopping agent of formula (I):

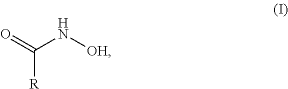

wherein R is selected from hydrogen, alkyl, heteroalkyl, cycloalkyl, heterocycloalkyl, aryl, and heteroaryl, each of which may be substituted or unsubstituted.

(20) In embodiment (20) is presented the polishing composition of embodiment (19), wherein the self-stopping agent is selected from hydroxamic acid, acetohydroxamic acid, benzhydroxamic acid, salicylhydroxamic acid, and combinations thereof.

(21) In embodiment (21) is presented the polishing composition of embodiment (19) or embodiment (20), wherein the self-stopping agent is hydroxamic acid.

(22) In embodiment (22) is presented the polishing composition of embodiment (19) or embodiment (20), wherein the self-stopping agent is benzhydroxamic acid.

(23) In embodiment (23) is presented the polishing composition of embodiment (19) or embodiment (20), wherein the self-stopping agent is salicylhydroxamic acid.

(24) In embodiment (24) is presented the polishing composition of any one of embodiments (1)-(23), wherein the polishing composition further comprises a conductivity adjust selected from an ammonium salt, a potassium salt, and a combination thereof.

(25) In embodiment (25) is presented the polishing composition of embodiment (24), wherein the conductivity adjust has a counterion selected from a nitrate, an acetate, a halide, a phosphate, and a sulfate.

(26) In embodiment (26) is presented the polishing composition of embodiment (24) or embodiment (25), wherein the conductivity adjust is selected from ammonium nitrate, ammonium chloride, ammonium bromide, ammonium acetate, potassium nitrate, potassium chloride, potassium bromide, potassium acetate, diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof.

(27) In embodiment (27) is presented the polishing composition of any one of embodiments (1)-(26), wherein the polishing composition has a conductivity of at least 170 μS/cm.

(28) In embodiment (28) is presented the polishing composition of any one of embodiments (1)-(27), wherein the polishing composition has a conductivity of at least 350 μS/cm.

(29) In embodiment (29) is presented a method of chemically-mechanically polishing a substrate comprising:
(i) providing a substrate,
(ii) providing a polishing pad,
(iii) providing a chemical-mechanical polishing composition comprising:
   (a) ceria abrasive particles;
   (b) a cationic polymer;
   (c) a buffer; and
   (d) water,
wherein the polishing composition has a pH of about 6 to about 9,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

(30) In embodiment (30) is presented the method of embodiment (29), wherein the polishing composition comprises about 0.001 wt. % to about 10 wt. % of the ceria abrasive particles.

(31) In embodiment (31) is presented the method of embodiment (29) or embodiment (30), wherein the polishing composition comprises about 0.05 wt. % to about 5 wt. % of the ceria abrasive particles.

(32) In embodiment (32) is presented the method of any one of embodiments (29)-(31), wherein the polishing composition has a pH of about 7 to about 9.

(33) In embodiment (33) is presented the method of any one of embodiments (29)-(32), wherein the polishing composition has a pH of about 7 to about 8.

(34) In embodiment (34) is presented the method of any one of embodiments (29)-(33), wherein cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof.

(35) In embodiment (35) is presented the method of embodiment (34), wherein the cationic monomer is selected from N-vinylimidazole, diallyldimethylammonium chloride (“DADMAC”), 2-(methacryloyloxy)-N,N,N-trimethylethanaminium chloride (“DMAEM.MCQ”), salts thereof, and combinations thereof.

(36) In embodiment (36) is presented the method of any one of embodiments (29)-(35), wherein the buffer is an amine-based compound comprising from one to five nitrogen atoms.

(37) In embodiment (37) is presented the method of any one of embodiments (29)-(36), wherein the buffer is a heterocyclic or heteroaromatic amine-based compound comprising from one to five nitrogen atoms.

(38) In embodiment (38) is presented the method of any one of embodiments (29)-(37), wherein the buffer comprises a heterocyclic or heteroaromatic amine selected from pyrrole, pyrrolidine, carbazole, isoindole, indole, pyrroline, indolizine, indoline, pyridine, piperidine, quinolizine isoquinoline, quinoline naphthyridine, imidazole, imidazoline, imidazolidine, tetrazole, triazole, benimidazole, purine, benzoxazole, benzthiazole, isothiazole, isoxazole, thiazole, oxazole, morpholine, thiomorpholine, pyrazole, pyrazoline, pteridine, triazine, pyrimidine, pyrazine, piperazine, indazole, pyridazine, and combinations thereof.

(39) In embodiment (39) is presented the method of any one of embodiments (29)-(38), where the buffer is benzotriazole, 5-aminotetrazole, or a combination thereof.

(40) In embodiment (40) is presented the method of any one of embodiments (29)-(39), wherein the polishing composition further comprises a conductivity adjust selected from an ammonium salt, a potassium salt, and a combination thereof.

(41) In embodiment (41) is presented the method of embodiment (40), wherein the conductivity adjust has a counterion selected from a nitrate, an acetate, a halide, a phosphate, and a sulfate.

(42) In embodiment (42) is presented the method of embodiment (40) or embodiment (41), wherein the conductivity adjust is selected from ammonium nitrate, ammonium chloride, ammonium bromide, ammonium acetate, potassium nitrate, potassium chloride, potassium bromide, potassium acetate, diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof.

(43) In embodiment (43) is presented the method of any one of embodiments (29)-(42), wherein the polishing composition has a conductivity of at least 170 μS/cm.

(44) In embodiment (44) is presented the method of any one of embodiments (29)-(43), wherein the polishing composition has a conductivity of at least 350 μS/cm.

(45) In embodiment (45) is presented the method of any one of embodiments (29)-(44), wherein the substrate comprises silicon oxide, silicon nitride, and polysilicon, and wherein at least a portion of the silicon oxide, silicon nitride, or polysilicon, is abraded at a removal rate to polish the substrate with a silicon oxide removal rate, a silicon nitride removal rate, and a polysilicon removal rate.

(46) In embodiment (46) is presented the method of embodiment (45), wherein the silicon oxide removal rate, the silicon nitride removal rate, and the polysilicon removal rate have an overall average removal rate, and each of the silicon oxide removal rate, the silicon nitride removal rate, and the polysilicon removal rate are within 20% of the overall average removal rate.

(47) In embodiment (47) is presented the method of embodiment (45), wherein the silicon oxide removal rate, the silicon nitride removal rate, and the polysilicon removal rate have an overall average removal rate, and each of the silicon oxide removal rate, the silicon nitride removal rate, and the polysilicon removal rate are within 15% of the overall average removal rate.

(48) In embodiment (48) is presented the method of embodiment (45), wherein the silicon oxide removal rate, the silicon nitride removal rate, and the polysilicon removal rate have an overall average removal rate, and each of the silicon oxide removal rate, the silicon nitride removal rate, and the polysilicon removal rate are within 10% of the overall average removal rate.

(49) In embodiment (49) is presented the method of any one of embodiments (29)-(45), wherein the polishing composition further comprises a nonionic polymer selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharide, and combinations thereof.

(50) In embodiment (50) is presented the method of embodiment (49), wherein the nonionic polymer is polyvinylpyrrolidone.

(51) In embodiment (51) is presented the method of embodiment (49), wherein the nonionic polymer is a polyalkylene glycol.

(52) In embodiment (52) is presented the method of embodiment (49), wherein the nonionic polymer is a polyethylene oxide/polypropylene oxide copolymer.

(53) In embodiment (53) is presented the method of any one of embodiments (49)-(52), wherein the substrate comprises silicon oxide, silicon nitride, and polysilicon, and wherein at least a portion of the silicon oxide, silicon nitride, or polysilicon, is abraded at a removal rate to polish the substrate with a silicon oxide removal rate, a silicon nitride removal rate, and a polysilicon removal rate, and wherein the silicon oxide removal rate, the silicon nitride removal rate, and the polysilicon removal rate have an overall average removal rate, and the polysilicon removal rate is at least 50% less than the overall average removal rate.

(54) In embodiment (54) is presented the method embodiment (53), wherein the silicon oxide removal rate, the silicon nitride removal rate, and the polysilicon removal rate have an overall average removal rate, and the polysilicon removal rate is at least 60% less than the overall average removal rate.

(55) In embodiment (55) is presented the method of embodiment (5e), wherein the silicon oxide removal rate, the silicon nitride removal rate, and the polysilicon removal rate have an overall average removal rate, and the polysilicon removal rate is at least 70% less than the overall average removal rate.

(56) In embodiment (56) is presented the method of any one of embodiments (29)-(45) and (49)-(52), wherein the polishing composition further comprises a cationic surfactant.

(57) In embodiment (57) is presented the method of embodiment (56), wherein the cationic surfactant comprises a quaternary ammonium salt.

(58) In embodiment (58) is presented the method of embodiment (56) or embodiment (57), wherein the cationic surfactant is selected from N,N,N′,N′,N′-pentamethyl-N-tallow alkyl-1,3-propanediammonium dichloride, (oxydi-2,1-ethanediyl)bis(coco alkyl)dimethyl ammonium dichlorides, salts thereof, and combinations thereof.

(59) In embodiment (59) is presented the method of any one of embodiments (29)-(45), (49)-(52), and (56)-(58), wherein the polishing composition comprises two or more cationic polymers.

(60) In embodiment (60) is presented the method of any one of embodiments (29)-(45), (49)-(52), and (56)-(59), wherein the conductivity adjust is selected from diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof.

(61) In embodiment (61) is presented the method of any one of embodiments (56)-(60), wherein the substrate comprises silicon oxide, silicon nitride, and polysilicon, and wherein at least a portion of the silicon oxide, silicon nitride, or polysilicon, is abraded at a removal rate to polish the substrate with a silicon oxide removal rate, a silicon nitride removal rate, and a polysilicon removal rate, and wherein the silicon oxide removal rate, the silicon nitride removal rate, and the polysilicon removal rate have an overall average removal rate, and the silicon oxide removal rate is at least 50% less than the overall average removal rate.

(62) In embodiment (62) is presented the method of embodiment (61), wherein the silicon oxide removal rate, the silicon nitride removal rate, and the polysilicon removal rate have an overall average removal rate, and the silicon oxide removal rate is at least 60% less than the overall average removal rate.

(63) In embodiment (63) is presented the method of embodiment (61), wherein the silicon oxide removal rate, the silicon nitride removal rate, and the polysilicon removal rate have an overall average removal rate, and the silicon oxide removal rate is at least 70% less than the overall average removal rate.

(64) In embodiment (64) is presented the method of any one of embodiments (29)-(45), (49)-(52), and (56)-(63), wherein the polishing composition further comprises a self-stopping agent of formula (I):

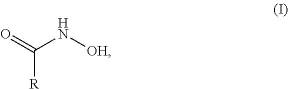

wherein R is selected from hydrogen, alkyl, heteroalkyl, cycloalkyl, heterocycloalkyl, aryl, and heteroaryl, each of which may be substituted or unsubstituted.

(65) In embodiment (65) is presented the method of embodiment (64), wherein the self-stopping agent is selected from hydroxamic acid, acetohydroxamic acid, benzhydroxamic acid, salicylhydroxamic acid, and combinations thereof.

(66) In embodiment (66) is presented the method of embodiment (64) or embodiment (65), wherein the self-stopping agent is hydroxamic acid.

(67) In embodiment (67) is presented the method of embodiment (64) or embodiment (65), wherein the self-stopping agent is benzhydroxamic acid.

(68) In embodiment (68) is presented the method of embodiment (64) or embodiment (65), wherein the self-stopping agent is salicylhydroxamic acid.

(69) In embodiment (69) is presented the method of any one of embodiments (64)-(68), wherein the substrate comprises silicon oxide, silicon nitride, and polysilicon, and wherein at least a portion of the silicon oxide, silicon nitride, or polysilicon, is abraded at a removal rate to polish the substrate with a silicon oxide removal rate, a silicon nitride removal rate, and a polysilicon removal rate, and wherein the silicon oxide removal rate, the silicon nitride removal rate, and the polysilicon removal rate have an overall average removal rate, and the silicon nitride removal rate is at least 50% less than the overall average removal rate.

(70) In embodiment (70) is presented the method of embodiment (69), wherein the silicon oxide removal rate, the silicon nitride removal rate, and the polysilicon removal rate have an overall average removal rate, and the silicon nitride removal rate is at least 60% less than the overall average removal rate.

(71) In embodiment (71) is presented the method of embodiment (69), wherein the silicon oxide removal rate, the silicon nitride removal rate, and the polysilicon removal rate have an overall average removal rate, and the silicon nitride removal rate is at least 70% less than the overall average removal rate.

### EXAMPLES

These following examples further illustrate the invention but, of course, should not be construed as in any way limiting its scope.

The following abbreviations are used throughout the Examples: removal rate (RR); tetraethyl orthosilicate (TEOS); silicon nitride (SiN); polysilicon (polySi); molecular weight (MW); and polyethylene glycol (PEG).

In the following examples, substrates, TEOS (i.e., silicon oxide), polySi, or SiN were coated on silicon, and were polished using either a MIRRA™ (Applied Materials, Inc.) polishing tool, an AP-300™ (CTS Co., Ltd) polishing tool, or a REFLEXION™ (Applied Materials, Inc.) polishing tool. An IC1010™ polishing pad (Rohm and Haas Electronic Materials) or an NEXPLANAR™ E6088 polishing pad (Cabot Microelectronics, Aurora, Ill.) were used with identical polishing parameters for all compositions.

Unless stated otherwise, standard REFLEXION™ polishing parameters are as follows: IC1010™ pad, downforce=20.68 kPa (3 psi), headspeed=85 rpm, platen speed=100 rpm, and total flow rate=250 mL/min.

Unless stated otherwise, standard AP300™ polishing parameters are as follows: IC1010™ pad, downforce=20.68 kPa (3 psi), headspeed=85 rpm, platen speed=100 rpm, and total flow rate=250 mL/min.

Unless stated otherwise, standard MIRRA™ polishing parameters are as follows: IC1010™ pad, downforce=20.68 kPa (3 psi), headspeed=85 rpm, platen speed=100 rpm, and total flow rate=250 mL/min; or NEXPLANAR™ E6088 pad downforce=13.79 kPa (2 psi), headspeed=85 rpm, platen speed=100 rpm, and total flow rate=250 mL/min.

Removal rates were calculated by measuring the film thickness, using spectroscopic elipsometry, and subtracting the final thickness from the initial thickness.

### Example 1

This example demonstrates the preparation of polishing compositions comprising (a) ceria abrasive particles, (b) a cationic polymer, and (c) a buffer, and optionally a cationic surfactant, nonionic polymer, and/or a self-stopping agent according to the invention. Inventive polishing compositions 1A-1O were used in Examples 2 and 3, below, to demonstrate the efficiency of the claimed polishing methods.

For each of the inventive Polishing Compositions 1A-1O used in Examples 2 and 3, each of ceria particles HC30™ and HC60™ (commercially available from Rhodia) were added in the amount shown in Table 1, e.g., for Polishing Composition 1A 0.16 wt. % HC30™ and 0.16 wt. % HC60™ were added. The ceria particles were combined with the cationic polymer, which for each of Polishing Compositions 1A-1O was polydiallyldimethylammonium chloride (“PolyDADMAC”) and/or poly-2-(methacryloyloxy)-N,N,N-trimethylethanaminium chloride (“PolyMADQUAT”), and the buffer, which for each of Polishing Compositions 1A-1O was 1H-benzotriazole (“BTA”). To each of the inventive Polishing Compositions 1A-1O was further added a biocide and the pH was adjusted to 7.5 with triethanolamine.

Inventive Polishing Compositions 1B-1F, 1I, 1J, 1N, and 10 further comprised cationic surfactant N,N,N′,N′,N′-pentamethyl-N-tallow alkyl-1,3-propanediammonium dichloride (“Duoquad T-50 HF”) in the amounts shown in Table 1.

Inventive Polishing Compositions 1C-1J further comprised one or more nonionic polymers, selected from PEG300, PEG1000, PEG4000, and PEG8000, in the amounts shown in Table 1.

Inventive Polishing Compositions 1K-10 further comprised one or more a self-stopping agent, selected from salicylhydroxamic acid (“SHA”) and benzhydroxamic acid (“BHA”), in the amounts shown in Table 1.

The resulting compositions are summarized in Table 1.

TABLE 1
Polishing Compositions

| | Ceria | | | Cationic | Nonionic | Stopping |
|---|---|---|---|---|---|---|
| Polishing | Wt. | Cationic Polymer | Buffer | Surfactant | Polymer | Agent |
| Composition | % | (PPm) | (PPm) | PPm | (PPm) | (PPm) |
| Polishing | 0.16 | PolyMADQUAT (100) | BTA | — | — | — |
| Composition 1A | | | (600) | | | |
| (Inventive) | | | | | | |
| Polishing | 0.13 | PolyMADQUAT (83) | BTA | 50 | — | — |
| Composition 1B | | | (500) | | | |
| (Inventive) | | | | | | |
| Polishing | 0.13 | PolyMADQUAT (83) | BTA | 50 | PEG300 | — |
| Composition 1C | | | (500) | | (500) | |
| (Inventive) | | | | | | |
| Polishing | 0.13 | PolyMADQUAT (83) | BTA | 35 | PEG300 | — |
| Composition 1D | | | (500) | | (500) | |
| (Inventive) | | | | | | |
| Polishing | 0.13 | PolyMADQUAT (83) | BTA | 25 | PEG300 | — |
| Composition 1E | | | (500) | | (500) | |
| (Inventive) | | | | | | |
| Polishing | 0.13 | PolyMADQUAT (83) | BTA | 50 | PEG300 | — |
| Composition 1F | | PolyDADMAC (25) | (500) | | (500) | |
| (Inventive) | | | | | | |
| Polishing | 0.11 | PolyMADQUAT (72) | BTA | — | PPG1000 | — |
| Composition 1G | | PolyDADMAC (25) | (429) | | (500) | |
| (Inventive) | | | | | | |
| Polishing | 0.11 | PolyMADQUAT (72) | BTA | — | PEG4000 | — |
| Composition 1H | | PolyDADMAC (25) | (429) | | (500) | |
| (Inventive) | | | | | | |
| Polishing | 0.11 | PolyMADQUAT (72) | BTA | 10 | PEG8000 | — |
| Composition 1I | | | (429) | | (1500) | |
| (Inventive) | | | | | | |
| Polishing | 0.13 | PolyMADQUAT(83) | BTA | 35 | PEG300 | — |
| Composition 1J | | | (500) | | (500) | |
| (Inventive) | | | | | PEG8000 | |
| | | | | | (1000) | |
| Polishing | 0.13 | PolyMADQUAT (83) | BTA | — | — | SHA |
| Composition 1K | | | (500) | | | (100) |
| (Inventive) | | | | | | |
| Polishing | 0.13 | PolyMADQUAT (83) | BTA | — | — | SHA |
| Composition 1L | | | (500) | | | (200) |
| (Inventive) | | | | | | |
| Polishing | 0.13 | PolyMADQUAT (83) | BTA | — | — | BHA |
| Composition 1M | | | (500) | | | (200) |
| (Inventive) | | | | | | |
| Polishing | 0.13 | PolyMADQUAT (83) | BTA | 100 | — | SHA |
| Composition 1N | | | (500) | | | (100) |
| (Inventive) | | | | | | |
| Polishing | 0.11 | PolyMADQUAT (72) | BTA | 100 | — | BHA |
| Composition 1O | | | (429) | | | (200) |
| (Inventive) | | | | | | |

### Example 2

This example demonstrates the beneficial polishing performance provided by a polishing composition containing a cationic surfactant and/or nonionic polymer prepared according to the invention.

Patterned substrates comprising TEOS, SiN, or polySi were polished with Polishing Compositions 1A-1E, as defined in Table 1 of Example 1, on a 300 mm AP-300™ (CTS Co., Ltd) polishing tool, with a IC1010™ pad (Rohm and Haas Electronic Materials), and a Saesol C7 conditioner (Saesol Diamond Ind. Co., Ltd, South Korea), using the following parameters: 93 rpm platen speed, 87 rpm head speed, 250 ml/min slurry flow. The polishing time was 30 seconds. Following polishing, the RR for TEOS, SiN, and polySi was determined, and the results are set forth in Table 2.

TABLE 2
Polishing Removal Rates and Selectivity as a Function
of Cationic Surfactant and/or Nonionic Polymer

| Polishing | Down Force | TEOS | SiN | PolySi | Selectivity |
|---|---|---|---|---|---|
| Composition | (psi) | (Å/min) | (Å/min) | (Å/min) | (TEOS:SiN:PolySi) |
| Polishing | 3 | 5682 | 1904 | 3028 | 1.0:0.3:0.5 |
| Composition 1A | | | | | |
| (Inventive) | | | | | |
| Polishing | 3 | 1180 | 1812 | 3314 | 1.0:1.5:2.8 |
| Composition 1B | | | | | |
| (Inventive) | | | | | |
| Polishing | 3 | 1022 | 1794 | 1800 | 1.0:1.8:1.8 |
| Composition 1C | | | | | |
| (Inventive) | | | | | |
| Polishing | 3 | 1528 | 1772 | 1860 | 1.0:1.2:1.2 |
| Composition 1D | | | | | |
| (Inventive) | | | | | |
| Polishing | 2 | 1336 | 1404 | 1286 | 1.0:1.1:1.0 |
| Composition 1D | | | | | |
| (Inventive) | | | | | |
| Polishing | 1 | 758 | 808 | 714 | 1.0:1.1:0.9 |
| Composition 1D | | | | | |
| (Inventive) | | | | | |
| Polishing | 3 | 2476 | 1808 | 1862 | 1.0:0.7:0.8 |
| Composition 1E | | | | | |
| (Inventive) | | | | | |
| Polishing | 2 | 1892 | 1458 | 1282 | 1.0:0.8:0.7 |
| Composition 1E | | | | | |
| (Inventive) | | | | | |
| Polishing | 1 | 1128 | 836 | 734 | 1.0:0.7:0.7 |
| Composition 1E | | | | | |
| (Inventive) | | | | | |

As is apparent from Table 2, inventive Polishing Composition 1A, containing HC-60™, HC-30™, polyMADQUAT, and BTA, only, exhibited removal rates of 5682 Å/min and 3028 Å/min for silicon oxide (i.e., TEOS) and polysilicon, respectively, which was relatively high compared to the removal rate for silicon nitride (1904 Å/min).

Table 2 also shows that adding a cationic surfactant, such as N,N,N′,N′,N′-pentamethyl-N-tallow alkyl-1,3-propanediammonium dichloride (“Duoquad T-50 HF”), reduces the polishing removal rate of silicon oxide (i.e., TEOS), while maintaining the removal rates of polysilicon and silicon nitride, as evidenced by the removal rates of Polishing Composition 1B as compared to the removal rates of Polishing Composition 1 Å. Similarly, Table 2 also shows that adding a nonionic polymer, such as PEG300, PEG1000, PEG4000, and/or PEG8000, reduces the polishing removal rate of polysilicon, while maintaining the removal rates of silicon oxide (i.e., TEOS) and silicon nitride, as evidenced by the removal rates of Polishing Composition 1C as compared to the removal rates of Polishing Composition 1B.

In addition, Table 2 shows that Polishing Compositions 1D and 1E, containing a cationic surfactant and a nonionic polymer, were nonselective for TEOS, SiN, or polySi. In other words, Polishing Compositions 1D and 1E exhibited approximately a 1:1:1 removal rate of TEOS:SiN:PolySi. Thus, the inventive polishing compositions, containing a cationic surfactant and a nonionic polymer, can be used to remove TEOS, SiN, or polySi at an equal rate.

### Example 3

This example demonstrates the beneficial polishing performance provided by a polishing composition containing a cationic surfactant, a nonionic polymer, and/or a self-stopping agent prepared according to the invention.

Patterned substrates comprising TEOS, SiN, or polySi were polished with Polishing Compositions 1D and 1F-10, as defined in Table 1 of Example 1, on a 300 mm AP-300™ (CTS Co., Ltd) polishing tool, with a Saesol C7 conditioner (Saesol Diamond Ind. Co., Ltd, South Korea), using the following parameters: 20.68 kPa (3 psi) down force, 250 ml/min slurry flow. The polishing time was 30 seconds. Following polishing, the RR for TEOS, SiN, and polySi was determined, and the results are set forth in Table 3.

TABLE 3
Polishing Removal Rates and Selectivity as a Function of Cationic
Surfactant, Nonionic Polymer, and/or Self-Stopping Agent

| | Table | Head | | | | | |
|---|---|---|---|---|---|---|---|
| Polishing | Speed | Speed | | TEOS | SiN | PolySi | Selectivity |
| Composition | (rpm) | (rpm) | Pad | (Å/min) | (Å/min) | (Å/min) | (TEOS:SiN:PolySi) |
| Polishing | 93 | 87 | IC1010 | 1528 | 1772 | 1860 | 1.0:1.2:1.2 |
| Composition 1D | | | | | | | |
| (Inventive) | | | | | | | |
| Polishing | 93 | 87 | IC1010 | 174 | 1444 | 1956 | 1.0:8.3:11 |
| Composition 1F | | | | | | | |
| (Inventive) | | | | | | | |
| Polishing | 93 | 87 | IC1010 | 314 | 1178 | 716 | 1.0:3.8:2.3 |
| Composition 1G | | | | | | | |
| (Inventive) | | | | | | | |
| Polishing | 59 | 53 | IC1010 | 172 | 1806 | 1380 | 1.0:11:8.0 |
| Composition 1H | | | | | | | |
| (Inventive) | | | | | | | |
| Polishing | 93 | 87 | IC1010 | 218 | 1376 | 982 | 1.0:6.3:4.5 |
| Composition 1I | | | | | | | |
| (Inventive) | | | | | | | |
| Polishing | 59 | 53 | IC1010 | 152 | 1506 | 1682 | 1.0:10:11 |
| Composition 1J | | | | | | | |
| (Inventive) | | | | | | | |
| Polishing | 93 | 87 | E6088 | 856 | 1066 | 376 | 1.0:1.2:0.4 |
| Composition 1K | | | | | | | |
| (Inventive) | | | | | | | |
| Polishing | 93 | 87 | IC1010 | 274 | 1674 | 638 | 1.0:6.1:2.3 |
| Composition 1L | | | | | | | |
| (Inventive) | | | | | | | |
| Polishing | 93 | 87 | E6088 | 128 | 120 | 2870 | 1.0:0.9:22 |
| Composition 1M | | | | | | | |
| (Inventive) | | | | | | | |
| Polishing | 93 | 87 | E6088 | 152 | 112 | 2628 | 1.0:0.7:17 |
| Composition 1N | | | | | | | |
| (Inventive) | | | | | | | |
| Polishing | 93 | 87 | E6088 | 1280 | 224 | 3208 | 1.0:0.2:2.5 |
| Composition 1O | | | | | | | |
| (Inventive) | | | | | | | |
| Polishing | 93 | 87 | E6088 | 1292 | 210 | 354 | 1.0:0.2:0.3 |
| Composition 1F | | | | | | | |
| (Inventive) | | | | | | | |
| Polishing | 93 | 87 | E6088 | 152 | 192 | 2834 | 1.0:1.3:19 |
| Composition 1G | | | | | | | |
| (Inventive) | | | | | | | |

As described in Example 2 above, Polishing Composition 1D was nonselective for TEOS, SiN, or polySi, exhibiting approximately a 1:1:1 removal rate of TEOS:SiN:PolySi. As exhibited by the results for inventive Polishing Compositions 1F-10, shown in Table 3, introducing additional components to nonselective Polishing Composition 1D can improve selectivity TEOS, SiN, or polySi.

As is apparent from Table 3, inventive Polishing Compositions 1F-1H, containing an additional cationic polymer (i.e., polyDADMAC), selectively reduced the removal rate of silicon oxide (i.e., TEOS) from greater than 1500 Å/min to less than 350 Å/min, while maintaining a relatively consistent removal rate of SiN and PolySi. Similarly, inventive Polishing Compositions 11 and 1J show that polishing compositions containing a higher molecular weight nonionic polymer (i.e., PEG 8000) can selectively reduce the removal rate of polysilicon. In addition, inventive Polishing Compositions 1K-1O show that polishing compositions containing a self-stopping agent (i.e., SHA or BHA) and/or a cationic surfactant can reduce the removal rates of SiN and TEOS, respectively. Thus, the inventive compositions provided herein can be modified to transition from a nonselective composition (e.g., Polishing Composition 1D) to a selective polishing composition by adding a cationic surfactant, a nonionic polymer, and/or a self-stopping agent.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) ceria abrasive particles;
(b) a cationic polymer, wherein the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof;
(c) a buffer, wherein the buffer is a heterocyclic or heteroaromatic amine-based compound comprising from one to five nitrogen atoms; and
(d) water,
wherein the polishing composition has a pH of about 6 to about 9.

2. The polishing composition of claim 1, wherein the polishing composition comprises about 0.001 wt. % to about 10 wt. % of the ceria abrasive particles.

3. The polishing composition of claim 1, wherein the polishing composition has a pH of about 7 to about 8.

4. The polishing composition of claim 1, wherein the polishing composition further comprises a nonionic polymer selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharide, and combinations thereof.

5. The polishing composition of claim 1, wherein the polishing composition further comprises a cationic surfactant.

6. The polishing composition of claim 1, wherein the polishing composition further comprises a self-stopping agent of formula (I): 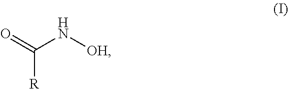
wherein R is selected from hydrogen, alkyl, heteroalkyl, cycloalkyl, heterocycloalkyl, aryl, and heteroaryl, each of which may be substituted or unsubstituted.

7. The polishing composition of claim 1, wherein the polishing composition further comprises a conductivity adjust selected from an ammonium salt, a potassium salt, and a combination thereof.

8. The polishing composition of claim 7, wherein the conductivity adjust is selected from ammonium nitrate, ammonium chloride, ammonium bromide, ammonium acetate, potassium nitrate, potassium chloride, potassium bromide, potassium acetate, diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof.

9. The polishing composition of claim 7, wherein the polishing composition has a conductivity of at least 170 μS/cm.

10. The polishing composition of claim 7, wherein the polishing composition has a conductivity of at least 350 μS/cm.

11. A method of chemically-mechanically polishing a substrate comprising:
(i) providing a substrate,
(ii) providing a polishing pad,
(iii) providing a chemical-mechanical polishing composition comprising:
(a) ceria abrasive particles;
(b) a cationic polymer, wherein the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof;
(c) a buffer, wherein the buffer is a heterocyclic or heteroaromatic amine-based compound comprising from one to five nitrogen atoms; and
(d) water,
wherein the polishing composition has a pH of about 6 to about 9,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

12. The method of claim 11, wherein the polishing composition comprises about 0.001 wt. % to about 10 wt. % of the ceria abrasive particles.

13. The method of claim 11, wherein the polishing composition has a pH of about 7 to about 8.

14. The method of claim 11, wherein the polishing composition further comprises a conductivity adjust selected from an ammonium salt, a potassium salt, and a combination thereof.

15. The method of claim 14, wherein the conductivity adjust is selected from ammonium nitrate, ammonium chloride, ammonium bromide, ammonium acetate, potassium nitrate, potassium chloride, potassium bromide, potassium acetate, diallyldimethylammonium chloride, tetrabutylammonium bromide, tetramethylammonium bromide, tetraethylammonium bromide, benzyltrimethylammonium bromide, tetrabutylammonium chloride, tetramethylammonium chloride, tetraethylammonium chloride, benzyltrimethylammonium chloride, tetrabutylammonium acetate, tetramethylammonium acetate, tetraethylammonium acetate, benzyltrimethylammonium acetate, and combinations thereof.

16. The method of claim 11, wherein the substrate comprises silicon oxide, silicon nitride, and polysilicon, and wherein at least a portion of the silicon oxide is abraded at a silicon oxide removal rate, wherein at least a portion of the silicon nitride is abraded at a silicon nitride removal rate, and wherein at least a portion of the polysilicon is abraded at a polysilicon removal rate to polish the substrate.

17. The method of claim 11, wherein the polishing composition further comprises a nonionic polymer selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharide, and combinations thereof.

18. The method of claim 11, wherein the polishing composition further comprises a cationic surfactant.

19. The method of claim 11, wherein the polishing composition further comprises a self-stopping agent of formula (I): 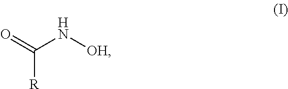
wherein R is selected from hydrogen, alkyl, heteroalkyl, cycloalkyl, heterocycloalkyl, aryl, and heteroaryl, each of which may be substituted or unsubstituted.

20. The method of claim 18, wherein the cationic surfactant is selected from N,N,N′,N′,N′-pentamethyl-N-tallow alkyl-1,3-propanediammonium dichloride, (oxydi-2,1-ethanediyl)bis(coco alkyl)dimethyl ammonium dichlorides, salts thereof, and combinations thereof.
